(19) United States
(12) Patent Application Publication
(10) Pub. No.: US 2025/0385167 A1
(43) Pub. Date: Dec. 18, 2025

(54) SEMICONDUCTOR MODULE AND SEMICONDUCTOR MODULE MANUFACTURING METHOD

(71) Applicant: FUJI ELECTRIC CO., LTD., Kawasaki-shi (JP)

(72) Inventor: Yuji SANO, Matsumoto-city (JP)

(73) Assignee: FUJI ELECTRIC CO., LTD., Kawasaki-shi (JP)

(21) Appl. No.: 19/194,157

(22) Filed: Apr. 30, 2025

(30) Foreign Application Priority Data
Jun. 12, 2024 (JP) 2024-095034

(51) Int. Cl. H01L 23/498; H01L 21/48; H01L 23/00; H01L 23/053; H01L 23/13

(52) U.S. Cl. CPC H01L 23/49811; H01L 21/4853; H01L 23/13; H01L 23/49838; H01L 23/053; H01L 24/32; H01L 24/48; H01L 24/73; H01L 2224/32225; H01L 2224/48225; H01L 2224/73265; H01L 2924/13055

(57) ABSTRACT

The semiconductor module includes an insulating substrate with an insulating plate and a metal plate joined to one face of the insulating plate; a tubular sleeve with a first end face joined to the metal plate and a second end face opposite to the first end face; and a pin inserted into the sleeve. At least one weld mark is formed by resistance welding on the first end face and a surface of the metal plate that faces the first end face, and an area of the at least one weld mark formed by resistance welding is less than an area of the first end face.

### CROSS REFERENCE TO RELATED APPLICATION

This application is based on, and claims priority from, Japanese Patent Application No. 2024-095034, filed Jun. 12, 2024, the entire content of which is incorporated herein by reference.

### BACKGROUND OF THE INVENTION

### Field of the Invention

The present disclosure relates to semiconductor modules and to a method of manufacturing semiconductor modules.

### Description of Related Art

A semiconductor module (a power semiconductor module being a typical example) generally includes an external terminal for electrically connecting a semiconductor chip to an external device. For example, Japanese Patent Application Laid-Open Publication No. 2019-153782 (Patent Document 1) describes that a pin is press-fitted into a sleeve that is joined to a substrate by soldering, welding, or bonding. U.S. Pat. No. 8,563,364 (Patent Document 2) describes joining a contact pin and a top metallization to each other by resistance welding. Japanese Patent Application Laid-Open Publication No. 2018-160554 (Patent Document 3) describes press-fitting an external connection terminal into a hollow hole of a contact component joined to a conductive pattern of a substrate by soldering. International Publication No. 2014/148319 (Patent Document 4) describes that an external output terminal is inserted into a hole of a contact component joined to an insulating substrate by soldering. International Publication No. 2013/89211 (Patent Document 5) describes press-fitting an implant pin into a tubular terminal connected to a metal layer of an insulating wiring board by soldering or the like.

In a case in which the substrate and the sleeve are joined to each other by soldering as in Patent Documents 3-5, there is a problem in that the sleeve is easily inclined or displaced relative to the substrate during a period between the melting and solidification of the solder. Furthermore, a joint portion formed by soldering is susceptible to deterioration due to temperature cycling if the load applied to the pin is concentrated on the joint portion between the substrate and the sleeve.

On the other hand, Patent Documents 1 and 2 do not describe the details of welding of the sleeve and the substrate to each other.

### SUMMARY OF THE INVENTION

In view of the above circumstances, an object of one aspect of the present disclosure is to enhance the reliability of a semiconductor module.

In order to solve the above problems, a semiconductor module according to an aspect of the present disclosure includes: an insulating substrate with an insulating plate and a metal plate joined to one face of the insulating plate; a tubular sleeve with a first end face joined to the metal plate and a second end face opposite to the first end face; and a pin inserted into the sleeve, in which at least one weld mark is formed by resistance welding on the first end face and a surface of the metal plate that faces the first end face, and an area of the at least one weld mark formed by resistance welding is less than an area of the first end face.

A method of manufacturing a semiconductor module according to an aspect of the present disclosure includes: a preparation step of preparing: an insulating substrate with an insulating plate and a metal plate joined to one face of the insulating plate, and a tubular sleeve with a first end face, a second end face opposite to the first end face, and an opening provided on the second end face; a joining step of joining the first end face to the metal plate by resistance welding; and an insertion step of inserting a pin into the sleeve, in which, in the joining step, a cross-sectional area of a current path by resistance welding between the metal plate and the first end face is less than an area of the first end face.

### BRIEF DESCRIPTION OF THE DRAWINGS

FIG. 1 is a cross-sectional view of a semiconductor module according to a first embodiment.

FIG. 2 is an explanatory view of a sleeve according to the first embodiment.

FIG. 3 is an explanatory view of weld marks between the sleeve and a metal plate according to the first embodiment.

FIG. 4 is a flowchart showing a method of manufacturing a semiconductor module according to the first embodiment.

FIG. 5 is an explanatory view of a preparation step according to the first embodiment.

FIG. 6 is a diagram showing an arrangement example of a plurality of projections.

FIG. 7 is an explanatory view of a joining step according to the first embodiment.

FIG. 8 is an explanatory view of an insertion step according to the first embodiment.

FIG. 9 is an explanatory view of a sleeve according to a second embodiment.

FIG. 10 is an explanatory view of a weld mark between the sleeve and the metal plate according to the second embodiment.

FIG. 11 is an explanatory view of a preparation step according to the second embodiment.

FIG. 12 is an explanatory view of a joining step according to the second embodiment.

FIG. 13 is an explanatory view of a joining step according to a third embodiment.

FIG. 14 is an explanatory view of second electrodes according to the third embodiment.

FIG. 15 is an explanatory view of weld marks between the sleeve and the metal plate according to a fourth embodiment.

FIG. 16 is an explanatory view of a joining step according to the fourth embodiment.

### DESCRIPTION OF THE EMBODIMENTS

Embodiments of the present disclosure will be described with reference to the drawings. In the drawings, the dimensions and scales of the respective parts may differ from actual products. The embodiments described below are exemplary forms envisioned in implementing the present disclosure. Therefore, the scope of the present disclosure is not limited to the following embodiments.

### 1. First Embodiment

### 1-1. Semiconductor Module

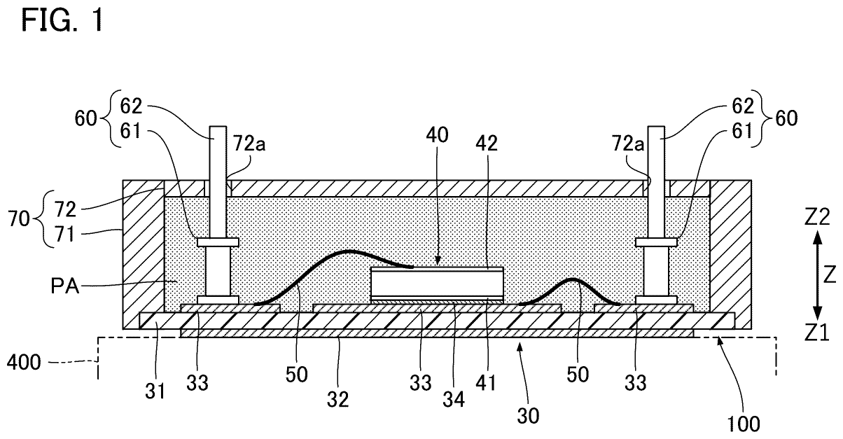

FIG. 1 is a cross-sectional view of a semiconductor module 100 according to a first embodiment. The semiconductor module 100 is a power semiconductor module, and is used in a power conversion device, such as an inverter circuit, for example. It is to be noted that, in FIG. 1, for convenience of explanation, the semiconductor module 100 is schematically illustrated, and the shape and the number of parts, or other forms, of the semiconductor module 100 are appropriately different from the actual forms.

As shown in FIG. 1, the semiconductor module 100 includes an insulating substrate 30, a semiconductor chip 40, a plurality of wires 50, a plurality of external terminals 60, a case 70, and a potting material PA.

In the following, the respective parts of the semiconductor module 100 will be described in order based on FIG. 1. A “Z-axis” is used as appropriate in the following explanation, for convenience. The Z axis is an axis parallel to the thickness direction or the height direction of the semiconductor module 100. In the following description, one direction along the Z-axis is a “Z1 direction” and the opposite direction to the Z1 direction is a “Z2 direction”. The relationship between these directions and the vertical direction is not particularly limited, and any relationship is possible. In the following, viewing in the direction along the Z-axis is sometimes referred to as a “plan view”.

The insulating substrate 30 is a wiring substrate on which the semiconductor chip 40 is installed. An insulating substrate 30 that may be used is, for example, a substrate such as a DCB (Direct Copper Bonding) substrate, an AMB (Active Metal Brazing) substrate, an IMS (Insulated Metal Substrate), or the like.

The insulating substrate 30 includes an insulating plate 31, a heat dissipation plate 32, and a plurality of metal plates 33, which are laminated together in the order of the plurality of metal plates 33, the insulating plate 31, and the heat dissipation plate 32 in the Z1 direction. The plurality of metal plates 33 is joined to one of the two faces of the insulating plate 31, and the heat dissipation plate 32 is joined to the other face.

The insulating plate 31 is a plate-shaped insulating member. The insulating plate 31 is made of, for example, a ceramic material such as aluminum oxide, aluminum nitride, silicon nitride, or the like, or a resin material such as an epoxy resin or the like.

The heat dissipation plate 32 is a thin-plate-shaped, high thermal conductor joined to a face of the insulating plate 31 that faces the Z1 direction. The heat dissipation plate 32 is made of metal, such as copper, aluminum, or the like. A heat dissipation structure 400 is joined to the heat dissipation plate 32, and heat generated in the semiconductor chip 40 is transferred to the heat dissipation structure 400 via the heat dissipation plate 32. The heat dissipation structure 400 is, for example, a structure such as a heat dissipation fin or the like, and is made of metal, such as aluminum, copper, or the like.

Each of the plurality of metal plates 33 is a thin-plate-shaped conductor joined to a face of the insulating plate 31 that faces the Z2 direction. Each metal plate 33 is made of a low-resistance, conductive material, such as copper, a copper alloy, or the like.

The semiconductor chip 40 is a power semiconductor element mounted on the insulating substrate 30, and is used as a switching element for switching between conducting and cutting off the current. The semiconductor chip 40 is, for example, an RC-IGBT (Reverse Conducting IGBT) including an IGBT (Insulated Gate Bipolar Transistor) and an FWD (Freewheeling Diode). The semiconductor chip 40 is joined to the metal plate 33 by a joining material 34. The joining material 34 is, for example, a conductive joining material such as a solder or the like.

The semiconductor chip 40 includes a first electrode 41, a second electrode 42, and a control electrode (not shown). One of the first electrode 41 and the second electrode 42 is an electrode to which a current to be controlled is input, and the other is an electrode from which the current is output. The first electrode 41 is a collector electrode constituting a first face of the semiconductor chip 40 that faces the Z1 direction, and also functions as a cathode electrode of the FWD. The first electrode 41 is joined to the metal plate 33 by the joining material 34. The second electrode 42 is an emitter electrode constituting a second face of the semiconductor chip 40 that faces the Z2 direction, and also functions as an anode electrode of the FWD. The control electrode is a gate electrode to which a control voltage is applied for controlling the switching of the semiconductor chip 40 between ON and OFF. The control electrode constitutes the second face of the semiconductor chip 40 that faces the Z2 direction, as with the second electrode 42.

Each of the plurality of wires 50 is a linear conductor that electrically connects the insulating substrate 30 and the respective parts of the semiconductor chip 40, as appropriate. The plurality of wires 50 includes a wire 50 connecting the metal plates 33 to each other, and a wire 50 connecting the metal plate 33 to the semiconductor chip 40.

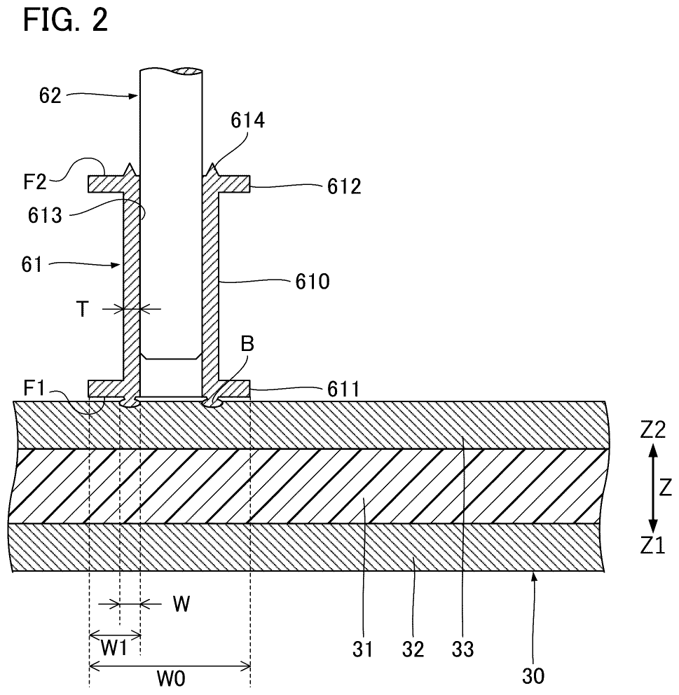

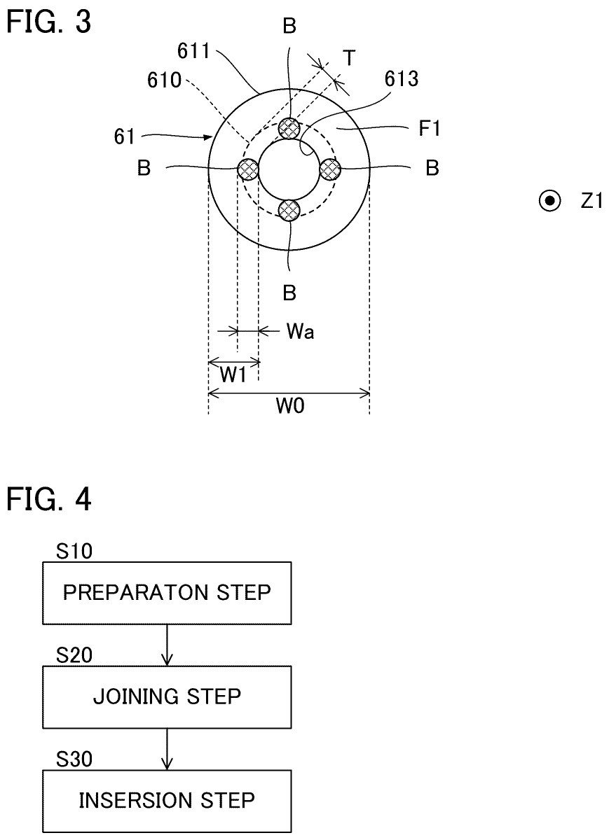

Each of the plurality of external terminals 60 is a terminal for electrically connecting the semiconductor chip 40 to an external apparatus. Each external terminal 60 has a sleeve 61 and a pin 62. The sleeve 61 is a tubular conductor and is joined to the metal plate 33 by resistance welding. The pin 62 is a rod-shaped conductor and is inserted into the sleeve 61. Each of the sleeve 61 and the pin 62 is made of a low-resistance metal, such as copper, a copper alloy, or the like. Each surface of the sleeve 61 and the pin 62 may be plated with, for example, tin, nickel or the like. The sleeve 61 will be described later with reference to FIGS. 2 and 3.

The case 70 is a structure that houses the semiconductor chip 40, the plurality of wires 50, and the sleeve 61 of the respective external terminals 60. The case 70 includes a frame 71 and a lid 72.

The frame 71 is a frame-shaped structure surrounding a collection of the semiconductor chip 40, the plurality of wires 50, and the sleeve 61 of the respective external terminals 60. The insulating substrate 30 is fixed to the frame 71 by, for example, an adhesive. The frame 71 is composed of a resin composition containing various insulating resins, such as a PPS (polyphenylene sulfide) resin, a PBT (polybutylene terephthalate) resin, a PBS (polybutylene succinate) resin, a PA (polyamide) resin, an ABS (acrylonitrile-butadiene-styrene) resin, or the like.

The lid 72 is a plate-shaped member that closes the opening of the frame 71. Like the frame 71, the lid 72 is made of a resin composition containing various insulating resins, such as a PPS (polyphenylene sulfide) resin, a PBT (polybutylene terephthalate) resin, a PBS (polybutylene succinate) resin, a PA (polyamide) resin, an ABS (acrylonitrile-butadiene-styrene) resin, or the like. The lid 72 is provided with a plurality of through holes 72a, and the pins 62 are inserted into the respective through holes 72a. With this configuration, a part of the respective pin 62 protrudes to the outside of the respective case 70. The lid 72 may be formed as a single body with the frame 71.

The potting material PA is an insulating material filled in an inner space surrounded by the insulating substrate 30 and the case 70. The potting material PA is made of, for example, a silicone resin, such as silicone gel, an epoxy resin, or the like. The potting material PA may include various fillers such as silicon oxide, aluminum oxide, or the like.

### 1-2. Sleeve of External Terminal

FIG. 2 is an explanatory view of the sleeve 61 according to the first embodiment. As shown in FIG. 2, the sleeve 61 includes a tubular portion 610, a first flange 611, and a second flange 612.

The tubular portion 610 is a part of the sleeve 61 and is a cylindrical portion having an inner circumferential surface 613, with an axis along the −Z axis as a central axis. The tubular portion 610 has one end (first end) in the Z1 direction and the other end (second end) in the Z2 direction. In the example illustrated in FIG. 2, each of the inner diameter and the outer diameter of the tubular portion 610 is constant over the entire region in the length direction. It is to be noted that the inner diameter and the outer diameter of the tubular portion 610 may not be constant. The cross-sectional shape of the tubular portion 610 is not limited to the example shown in FIG. 2, and may be freely selected.

The first flange 611 is a part of the sleeve 61 and is an annular portion protruding radially outward from the first end of the tubular portion 610. The second flange 612 is a part of the sleeve 61 and is an annular portion protruding radially outward from the second end of the tubular portion 610. One or both of the first flange 611 and the second flange 612 may be omitted.

The sleeve 61 has a first end face F1 and a second end face F2. The first end face F1 is the end face of the sleeve 61 in the Z1 direction. The second end face F2 is an end face opposite to the first end face F1 and is the end face of the sleeve 61 in the Z2 direction.

In the embodiment shown in FIG. 2, the first end face F1 comprises a plane perpendicular to the Z-axis and is constituted of an end face of the tubular portion 610 that faces the Z1 direction and a face of the first flange 611 that faces the Z1 direction. The second end face F2 is a plane perpendicular to the Z-axis and constituted of an end face of the tubular portion 610 that faces the Z2 direction and a face of the second flange 612 that faces the Z2 direction.

Each of the first end face F1 and the second end face F2 of the present embodiment is provided with an opening that communicates with the inner space of the tubular portion 610. A part of the pin 62 is inserted into the sleeve 61 through the opening provided in the second end face F2. The pin 62 is fixed to the sleeve 61 by being press-fitted into the sleeve 61, for example. The fixing of the pin 62 to the sleeve 61 is not limited to press-fitting, and may be, for example, fixing by soldering or the like. In addition, the cross-sectional shape of the pin 62 is not limited to the example shown in FIG. 2 and can be freely selected. The first end face F1 may not have an opening communicating with the inner space of the tubular portion 610.

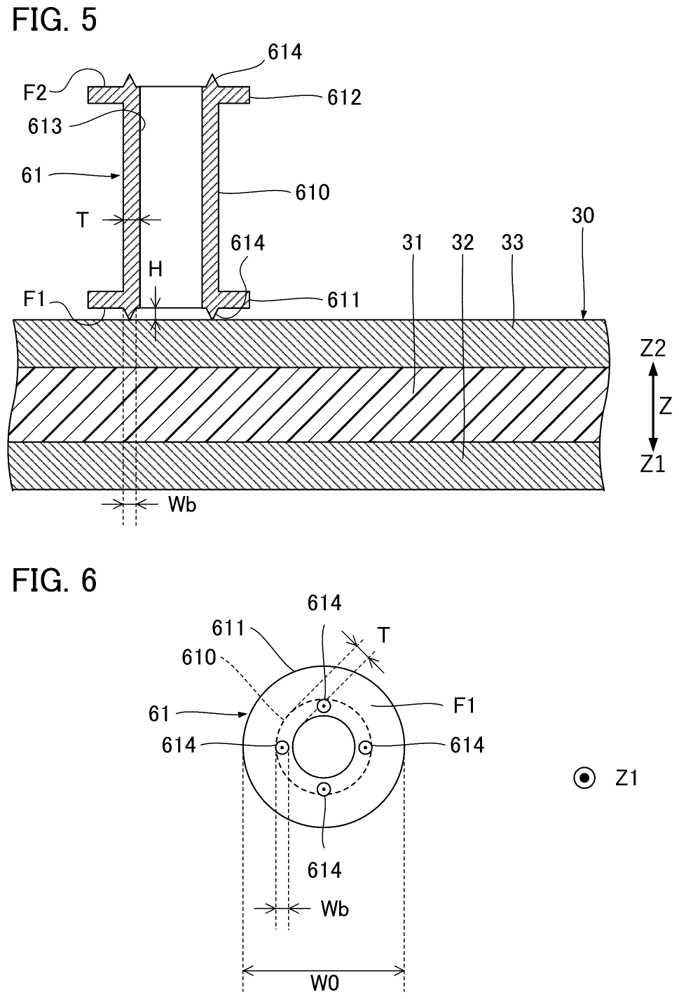

The first end face F1 is joined to the metal plate 33 via a plurality of weld marks B formed by resistance welding. The respective weld marks B are marks formed by joining the projections 614 provided on the first end face F1 to the metal plate 33 by resistance welding in a manufacturing method, described later. A weld mark B is formed as a single body with both the sleeve 61 and the metal plate 33. The projections 614 will be described later with reference to FIG. 5. In FIG. 2, for convenience of explanation, the boundary between the weld marks B and the metal plate 33 is clearly shown, but in actuality, the boundary may not be clear due to a gradient in metal composition or the like. Furthermore, in the present embodiment, a plurality of projections 614 is provided also on the second end face F2, and this will be described later with reference to FIG. 5.

In the embodiment illustrated in FIG. 2, the first end face F1 is disposed with a gap relative to the metal plate 33 in an area other than the weld marks B. The first end face F1 may have a portion that contacts the metal plate 33 in an area other than the weld marks B.

As described above, since the sleeve 61 is joined to the metal plate 33 by resistance welding, an advantage (first advantage) is obtained in that the sleeve 61 is only slightly inclined or displaced relative to the substrate when the metal plate 33 and the sleeve 61 are joined to each other. Furthermore, the join strength between the metal plate 33 and the sleeve 61 can be increased, as compared with a configuration in which the sleeve 61 is joined to the metal plate 33 by soldering. Therefore, even if the load applied to the pin 62 is concentrated at the joined portion between the metal plate 33 and the sleeve 61, an advantage (second advantage) is also obtained in that the joined portion between the metal plate 33 and the sleeve 61 is only slightly affected by deterioration due to temperature cycling.

FIG. 3 is an explanatory view of the weld marks B between the sleeve 61 and the metal plate 33 according to the first embodiment. In FIG. 3, cross sections of the weld mark B taken along the plate surface of the metal plate 33 are shown together with a plan view of the first end face F1. As shown in FIG. 3, the weld marks B are scattered on the first end face F1. Therefore, the area of the weld marks B is smaller than the area of the first end face F1. As a result, the time required for joining the metal plate 33 and the sleeve 61 to each other can be shortened. Therefore, the first advantage is preferably obtained, and the heat generated when joining the metal plate 33 and the sleeve 61 is prevented from adversely affecting the other parts. The area of the weld marks B is the sum of the areas of the plurality of weld marks B.

In the present embodiment, the metal plate 33 and the sleeve 61 are joined to each other via the plurality of weld marks B. The weld marks B of the present embodiment are circumferentially scattered along the outer periphery or the inner periphery of the first end face F1. This configuration can stabilize the orientation of the sleeve 61 during resistance welding, eliminating the need to form a recessed portion on the metal plate 33 for inserting the first end face F1. Furthermore, after resistance welding, as compared with a configuration in which the weld marks B are arranged in an offset manner on one side of the first end face F1 and are not equally spaced, there is also an advantage in that the join strength between the metal plate 33 and the sleeve 61 is easily increased.

In the example shown in FIG. 3, the weld marks B comprise four weld marks B. The four weld marks B are arranged at equal intervals circumferentially along the inner periphery of the first end face F1. In the manufacturing method described later, the number and arrangement of the weld marks B are determined based on the number and arrangement of the projections 614 provided on the first end face F1, and therefore are not limited to the embodiment shown in FIG. 3 and may be freely selected.

The size of the respective weld mark B is determined to some extent based on the size of the corresponding projection 614 formed on the first end face F1 in the manufacturing method described later. The width Wa of the respective weld mark B only has to be less than the width W0 of the first end face F1, but in the present embodiment, the width Wa is less than the distance W1 between the inner periphery and the outer periphery of the first end face F1.

In the example shown in FIG. 3, each and every weld mark B overlaps the tubular portion 610 as viewed in the direction along the Z-axis. As a result, a current can be efficiently supplied to the projections 614 (described later) during resistance welding. It is to be noted that at least one of the plurality of weld marks B may overlap the first flange 611 without overlapping the tubular portion 610 when viewed in the direction along the Z-axis. In a case in which more than one weld mark B overlaps the first flange 611 when viewed in the direction along the Z-axis, an advantage is obtained in that it is easy to stabilize the orientation of the sleeve 61 relative to the metal plate 33 in a joining step S20 of the manufacturing method described later.

The width Wa of each weld mark B is preferably 0.5 times or more and 1.5 times or less than the thickness T of the tubular portion 610. This advantageously prevents the heat generated at the time of joining the metal plate 33 and the sleeve 61 to each other from adversely affecting other parts.

As described above, by performing the resistance welding of the projections 614 provided, spatter is suppressed, unlike forming weld marks using other methods. As a result, the width Wa of the respective weld mark B will remain 0.5 times or more and 1.5 times or less relative to the thickness T of an opposing portion of the sleeve that opposes the weld mark B, and the area of the weld mark B will be about ⅓ to 1 times the area of the opposing portion. In a case in which the plurality of projections 614 is used, the same weld mark B as described above is obtained for each of the plurality of projections 614.

### 1-3. Method of Manufacturing Semiconductor Modules

FIG. 4 is a flowchart illustrating a method of manufacturing the semiconductor module 100 according to the first embodiment. As illustrated in FIG. 4, the manufacturing method of the semiconductor module 100 includes a preparation step S10, a joining step S20, and an insertion step S30 in this order. In the following, each step will be described in order.

FIG. 5 is an explanatory view of the preparation step S10 in the first embodiment. In the preparation step S10, as shown in FIG. 5, the insulating substrate 30 and the sleeve 61 are prepared.

In the preparation step S10 before the joining step S20, a sleeve is prepared for which a plurality of projections 614 is provided on the first end face F1. The projections 614 provided on the first end face F1 are exemplary “first projections”. The projections 614 provided on the first end face F1 are projections for realizing projection welding, and will serve as the above-described weld marks B through resistance welding in the joining step S20.

In the present embodiment, a plurality of projections 614 is also provided on the second end face F2. The projections 614 provided on the second end face F2 are exemplary “second projections”. In the preparation step S10, the sleeve 61 is symmetrically shaped in the length direction. The resultant sleeve 61 has no top-bottom distinction. Therefore, it is possible to increase the working efficiency of the resistance welding. However, the sleeve 61 may have an asymmetrical shape in the length direction. The projections 614 on the second end face F2 may be omitted.

Each projection 614 has a tapered shape. In other words, the width of each projection 614 decreases toward the distal tip. Accordingly, a current can be effectively concentrated between the metal plate 33 and the sleeve 61 during resistance welding in the joining step S20. In the example shown in FIG. 5, each projection 614 has a conical shape. However, the shape of each projection 614 is not limited to the example shown in FIG. 5, and may be, for example, a pyramidal shape, a truncated cone shape, a truncated pyramidal shape, or a shape with a constant width.

The height H of each projection 614 is preferably not less than 0.5 times and not more than 2 times the thickness T of the tubular portion 610. Accordingly, the current can be effectively concentrated between the metal plate 33 and the sleeve 61 while preventing the heat from adversely affecting other parts during the resistance welding in the joining step S20.

FIG. 6 is a diagram illustrating an arrangement example of the plurality of projections 614. In the embodiment illustrated in FIG. 6, the number of the plurality of projections 614 provided on the first end face F1 is four. The four projections 614 are arranged at equal intervals circumferentially along the outer periphery of the first end face F1.

As described above, with the plurality of projections 614 provided on the first end face F1, it is possible to stabilize the orientation of the sleeve 61 during resistance welding in the joining step S20, eliminating the need to form a recessed portion on the metal plate 33 for inserting the first end face F1. The number of projections 614 is not limited to the example shown in FIG. 6, and the number may be three or fewer, or be five or more. However, from the viewpoint of achieving both stability in orientation of the sleeve 61 during resistance welding and efficiency of resistance welding, the number of projections 614 provided on the first end face F1 must be three or more, and is preferably three or more and seven or fewer.

The width Wb of the respective projection 614 only has to be smaller than the width W0 of the first end face F1, and is preferably 0.5 times or more and 1.5 times or less relative to the thickness T of the tubular portion 610. With this configuration, it is possible to prevent heat generated when the metal plate 33 and the sleeve 61 are joined to each other in the joining step S20, from adversely affecting the other parts.

In the example illustrated in FIG. 6, each projection 614 overlaps the tubular portion 610 in a direction along the Z-axis. As a result, current can be efficiently supplied to the projections 614 during resistance welding in the joining step S20. At least one of the plurality of projections 614 may overlap the first flange 611 without overlapping the tubular portion 610 when viewed in the direction along the Z-axis. In a case in which more than one of the projections 614 overlap the first flange 611 in the direction along the Z-axis, an advantage is obtained in that the orientation of the sleeve 61 relative to the metal plate 33 is easily stabilized in the joining step S20.

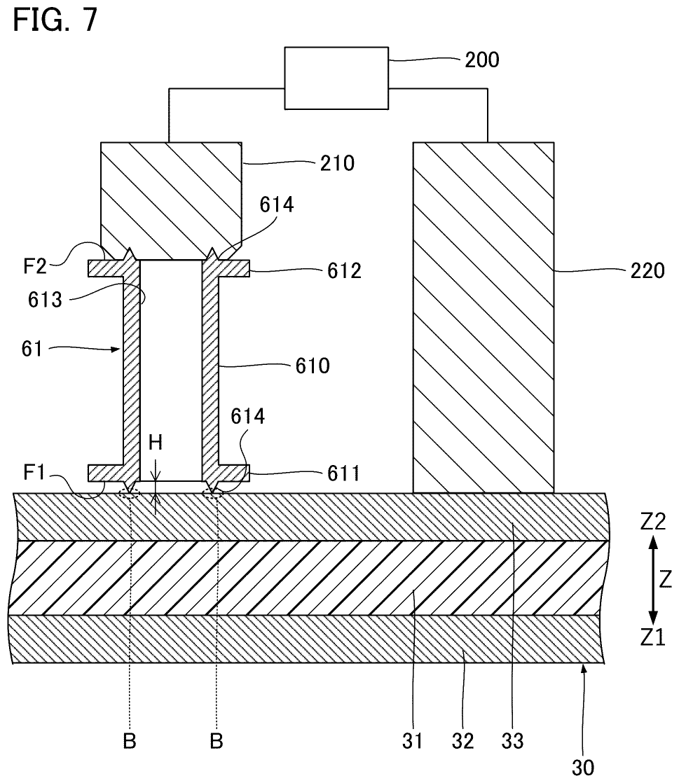

FIG. 7 is an explanatory view of the joining step S20 according to the first embodiment. In the joining step S20, the first end face F1 is joined to the metal plate 33 by resistance welding.

Specifically, the first electrode 210 is first connected to the sleeve 61 to be welded, and the second electrode 220 is connected to the metal plate 33 to be welded. Then, a power source 200 of a resistance welding machine supplies a current to flow between the first electrode 210 and the second electrode 220, thereby generating Joule heating at the contact point between the projections 614 and the metal plate 33. Thus, in the joining step S20, the metal plate 33 and the plurality of projections 614 are joined by resistance welding. During the welding, each projection 614 melts into the metal plate 33 to form a weld mark B.

The power source 200 is not particularly limited, and for example, a power source of a known resistance welding machine may be used. Each of the first electrode 210 and the second electrode 220 is made of a material, such as tungsten, molybdenum, or the like, that slightly forms an alloy with the sleeve 61. In addition, from the viewpoint of minimizing the electric resistivity between the first electrode 210 and the sleeve 61, it is preferable that the first electrode 210 contact the second end face F2 over the entire area. That is, the contact area between the first electrode 210 and the sleeve 61 is preferably equal to or greater than the contact area between the projections 614 and the metal plate 33. For example, in the present embodiment, the plurality of projections 614 is provided on the second end face F2. Therefore, the contact area between the first electrode 210 and the sleeve 61 can be made approximately the same as the area of the second end face F2 by providing, on the first electrode 210, a recessed portion shaped to accommodate (i.e., so as to avoid) the projections 614. Furthermore, the alignment between the sleeve 61 and the first electrode 210 is not easy if the cross-sectional shape of the sleeve 61 is circular. Therefore, to facilitate alignment, it is preferable that the respective cross-sectional shapes of the sleeve 61 and the first electrode 210 be polygonal, such as hexagonal, octagonal, or the like, and that the number and the positions of the projections 614 match the cross-sectional shape of the sleeve 61. Alternatively or additionally, it is preferable that a mark such as a notch or the like on each of the sleeve 61 and the first electrode 210 be provided. Furthermore, the shape of the first electrode 210 may be concave to press against the surrounding areas of the projections 614 on the second end face F2. From the viewpoint of minimizing the electrical resistance between the second electrode 220 and the metal plate 33, the contact area between the second electrode 220 and the metal plate 33 is preferably equal to or greater than the contact area between the projections 614 and the metal plate 33.

In the present embodiment, as described above, the second end face F2 uses the face of the second flange 612. In other words, the second flange 612 of the sleeve 61 is a flange including the second end face F2. Accordingly, the contact area between the first electrode 210, which is an electrode for resistance welding, and the second end face F2 can be increased.

The joining step S20 thus performs resistance welding by applying a current between the first electrode 210, which is in contact with the sleeve 61, and the second electrode 220, which is in contact with one face of the metal plate 33. Accordingly, even if the insulating plate 31 is provided on the other face of the metal plate 33, a current for resistance welding can flow between the metal plate 33 and the first end face F1 of the sleeve 61.

By joining the first end face F1 to the metal plate 33 by resistance welding, a first advantage is obtained in that during the resistance welding, the sleeve 61 is only slightly inclined or displaced relative to the substrate when the metal plate 33 and the sleeve 61 are joined. Furthermore, the join strength between the metal plate 33 and the sleeve 61 can be increased, as compared with a mode in which the sleeve 61 is joined to the metal plate 33 by soldering. Therefore, even if the load applied to the pin 62 is concentrated at the joined portion between the metal plate and the sleeve 61, a second advantage is also obtained in that the joined portion between the metal plate 33 and the sleeve 61 is only slightly affected by the deterioration due to the temperature cycling.

The current flowing between the first electrode 210 and the second electrode 220 flows between the metal plate 33 and the sleeve 61 through the projections 614. Thus, the metal plate 33 and the first end face F1 can be joined by projection welding. In the joining step S20, the cross-sectional area of the current path by the resistance welding between the metal plate 33 and the first end face F1 is smaller than the area of the first end face F1. As a result, the time required for joining the metal plate 33 and the sleeve 61 to each other can be shortened. Therefore, the above-described first advantage is preferably obtained, and the heat generated at the time of joining the metal plate 33 and the sleeve 61 is prevented from adversely affecting the other parts.

As described above, since the width Wb of the respective projection 614 is smaller than the width W0 of the sleeve 61, the cross-sectional area of the current path by resistance welding between the metal plate 33 and the first end face F1 can be made smaller than the area of the first end face F1.

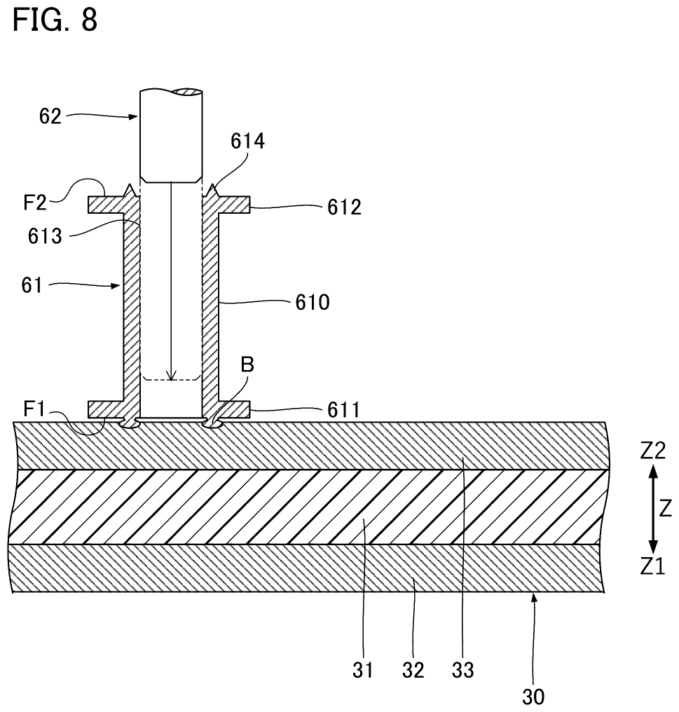

FIG. 8 is an explanatory view of the insertion step S30 according to the first embodiment. In the insertion step S30, as shown in FIG. 8, the pin 62 is inserted into the sleeve 61. The pin 62 is fixed to the sleeve 61 by being press-fitted into the sleeve 61, for example. The fixing of the pin 62 to the sleeve 61 is not limited to press-fitting, and may be, for example, fixing by soldering or the like.

Although not shown, between the joining step S20 and the insertion step S30, the semiconductor chip 40 is mounted on the insulating substrate 30, followed by the formation of the plurality of wires 50, for example. After the insertion step S30, for example, the case 70 is attached, followed by the formation of the potting material PA. The semiconductor module 100 is thus obtained.

As described above, in the method of manufacturing the semiconductor module 100 according to the present embodiment, the reliability of the semiconductor module 100 can be improved.

### 2. Second Embodiment

In the following, a second embodiment of the present disclosure will be described. In the embodiment illustrated below, elements for which actions and functions are the same as those of the above-described embodiment will be described with reference to the reference numerals used in the description of the above-described embodiment, and detailed descriptions thereof will be omitted as appropriate.

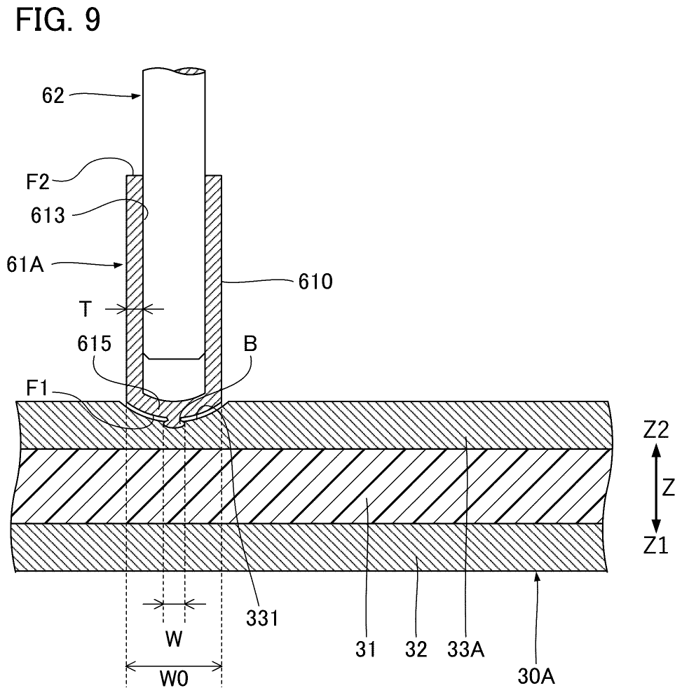

FIG. 9 is an explanatory view of a sleeve 61A according to the second embodiment. The present embodiment is the same as the first embodiment except that the insulating substrate 30A and the sleeve 61A are used in place of the insulating substrate 30 and the sleeve 61 of the first embodiment.

The insulating substrate 30A is configured similarly to the insulating substrate 30 of the first embodiment, except that a metal plate 33A is provided in place of the metal plate 33 of the first embodiment. The metal plate 33A is configured in the same manner as the metal plate 33 of the first embodiment, except for having a recessed portion 331.

The recessed portion 331 is for receiving the first end face F1, and is shaped to correspond to the first end face F1. In the example illustrated in FIG. 9, the recessed portion 331 has a concave, curved shape. However, the shape of the recessed portion 331 may be determined in accordance with the shape of the first end face F1, and is not limited to the example illustrated in FIG. 9.

The sleeve 61A is configured similarly to the sleeve 61 of the first embodiment except that the first flange 611 and the second flange 612 of the first embodiment are omitted and a bottom portion 615 is added. In the sleeve 61A, the projections 614 on the second end face F2 are also omitted.

The tubular portion 610 has an opening in the Z1 direction. The bottom portion 615 is a part of the sleeve 61A that closes the opening of the tubular portion 610 in the Z1 direction. With the bottom portion 615 being provided in the described configuration, the sleeve 61A has a tubular shape with a bottom, the first end face F1 being a bottom face.

In the embodiment illustrated in FIG. 9, the first end face F1 is constituted of an end face of the tubular portion 610 in the Z1 direction and a face of the bottom portion 615 that faces the Z1 direction, and has a curved shape that protrudes toward the insulating plate 31. Furthermore, the second end face F2 is constituted of an end face of the tubular portion 610 that is in the Z2 direction. The second end face F2 is a plane perpendicular to the Z-axis.

The first end face F1 of the present embodiment is joined to the metal plate 33A via a single weld mark B. The first end face F1 is inserted into the recessed portion 331, thereby stabilizing the position and orientation of the sleeve 61B during resistance welding. In the embodiment illustrated in FIG. 9, the first end face F1 is disposed with a gap from the wall surface of the recessed portion 331 in an area other than the weld mark B. The first end face F1 may have a part that is in contact with the wall surface of the recessed portion 331 in the area other than the weld mark B.

The weld mark B of the present embodiment is located at the center of the first end face F1. Accordingly, the weld mark B includes the center of the first end face F1. With this configuration, it is easier to concentrate the current at the center of the first end face F1 during resistance welding, so that the time required for joining the metal plate 33A and the sleeve 61 can be extremely short. In the present embodiment, the number of weld marks B, i.e., the number of the projections 614, may be multiple. For example, in place of the weld mark B or the projection 614 including the center of the first end face F1, or in addition to the weld mark B or the projection 614 including the center of the first end face, a plurality of the weld marks B or a plurality of the projections 614 may be provided so as to be scattered along the circumferential direction of the inner periphery or the outer periphery of the first end face F1.

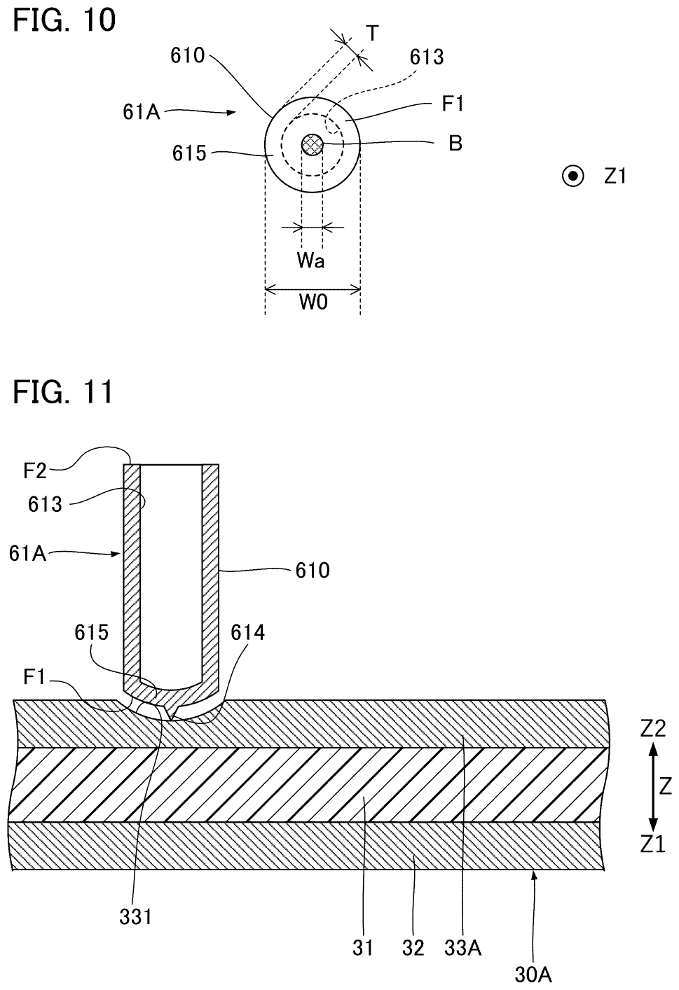

FIG. 10 is an explanatory view of the weld mark B between the sleeve 61A and the metal plate 33A according to the second embodiment. In FIG. 10, a cross section of the weld mark B taken along the plate surface of the metal plate 33A is shown together with a plan view of the first end face F1. As shown in FIG. 10, a single weld mark B is provided on the first end face F1, and the area of the weld mark B is smaller than the area of the first end face F1. Accordingly, the time required for joining the metal plate 33A and the sleeve 61A to each other can be shortened.

FIG. 11 is an explanatory view of the preparation step S10 according to the second embodiment. In the preparation step S10 of the present embodiment, as shown in FIG. 11, the insulating substrate 30A and the sleeve 61A are prepared.

In the preparation step S10 before the joining step S20, a projection 614 is provided on the first end face F1 of the present embodiment. The projection 614 is located at the center of the first end face F1. Accordingly, the projection 614 includes a projection that includes the center of the first end face F1. With this configuration, it is easier to concentrate the current at the center of the first end face F1 during resistance welding, so that the time required for joining the metal plate 33A and the sleeve 61 to each other can be extremely short.

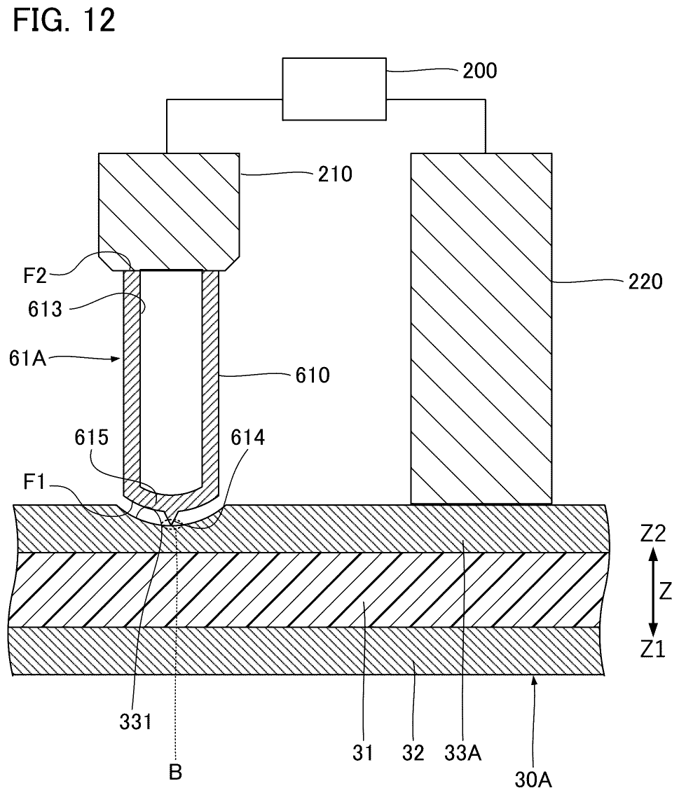

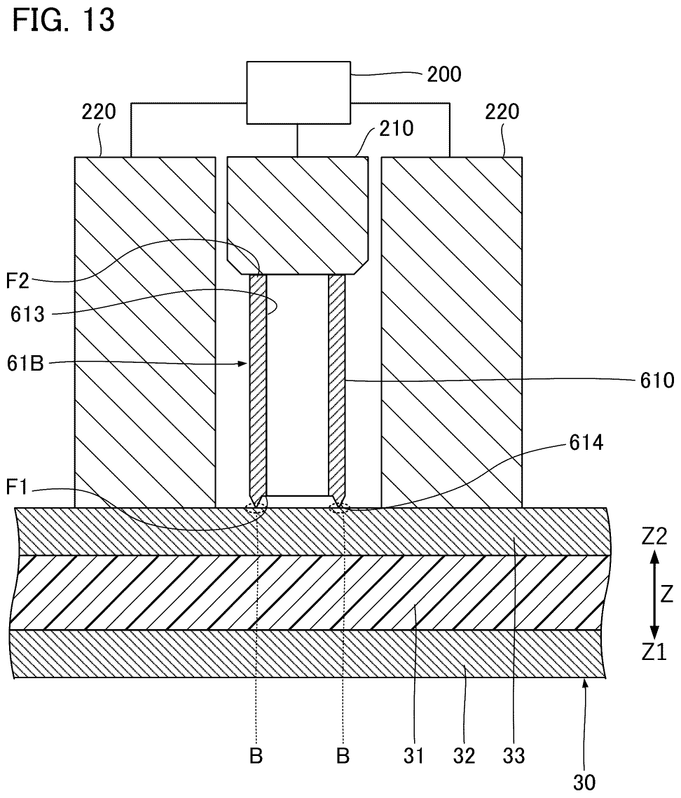

FIG. 12 is an explanatory view of the joining step S20 according to the second embodiment. In the joining step S20 of the present embodiment, the first end face F1 of the sleeve 61A is joined to the metal plate 33A by resistance welding. Through resistance welding, the projection 614 provided on the first end face F1 melts into the metal plate 33A, thereby forming a weld mark B.

In the joining step S20 of the present embodiment, the first end face F1 is inserted into the recessed portion 331. As a result, the position and orientation of the sleeve 61 during resistance welding can be stabilized.

In the present embodiment, as described above, because the first end face F1 is curved to protrude toward the insulating plate 31, it is possible to make the portion other than the center of the first end face F1 unlikely to come into contact with the metal plate 33A during resistance welding. Therefore, it is easy to concentrate the current on the center of the first end face F1 during resistance welding. Furthermore, in the present embodiment, since the plurality of projections 614 is not provided on the second end face F2, the contact area between the first electrode 210 and the sleeve 61A can be easily increased without requiring any modification to the shape of the first electrode 210.

After the above-described joining step S20, the insertion step S30 as well as the other steps are executed as in the first embodiment. According to the second embodiment described above, the reliability of the semiconductor module can also be improved.

### 3. Third Embodiment

In the following, a third embodiment of the present disclosure will be described. In the embodiment illustrated below, elements for which actions and functions are the same as those of the above-described embodiment will be described with use of the reference numerals used in the description of the above-described embodiment, and detailed descriptions thereof will be omitted as appropriate.

FIG. 13 is an explanatory view of the joining step S20 according to the third embodiment. The joining step S20 of the present embodiment is the same as the joining step S20 of the first embodiment except that the configuration of the second electrode 220 differs and that jigs 310 and 320 are used. FIG. 13 illustrates a configuration in which the sleeve 61B is used in place of the sleeve 61 of the first embodiment.

The sleeve 61B is configured similarly to the sleeve 61 of the first embodiment, except that the first flange 611, the second flange 612, and the plurality of projections 614 of the second end face F2 of the first embodiment are omitted. By omitting the first flange 611 and the second flange 612, an advantage is obtained in that the distance between the first electrode 210 and the second electrode 220 can be reduced easily. It is to be noted that, in the present embodiment, one or both of the first flange 611 and the second flange 612 may or may not be omitted.

In the joining step S20 of the present embodiment, a plurality of second electrodes 220 surrounding the sleeve 61 is used. As a result, the current path between the first electrode 210 and the respective second electrode 220 can be shortened, and the current between the metal plate 33 and the first end face F1 can be made uniform.

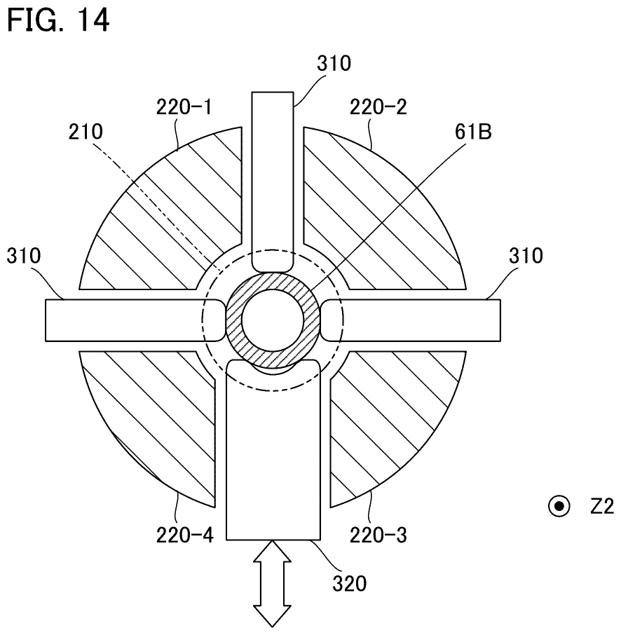

FIG. 14 is an explanatory view of second electrodes 220-1 to 220-4 according to the third embodiment. In FIG. 14, a cross section is shown in which the second electrodes 220-1 to 220-4 and the sleeve 61B are cut in a plane perpendicular to the Z-axis. Each of the second electrodes 220-1 to 220-4 is the second electrode 220. In the following description, the second electrodes 220-1 to 220-4 may be referred to as second electrodes 220 without distinguishing them.

The second electrodes 220-1, 220-2, 220-3, and 220-4 are circumferentially spaced apart from each other around the sleeve 61B, in this order. The space between the second electrode 220-3 and the second electrode 220-4 is greater than the width of the sleeve 61B. Accordingly, the sleeve 61B can be introduced through the space between the second electrode 220-3 and the second electrode 220-4 into the area surrounded by the second electrodes 220-1 to 220-4.

In the example shown in FIG. 14, the space between the second electrode 220-1 and the second electrode 220-4, the space between the second electrode 220-1 and the second electrode 220-2, and the space between the second electrode 220-2 and the second electrode 220-3 are each smaller than the space between the second electrode 220-3 and the second electrode 220-4. Accordingly, the contact area between the second electrodes 220 and the metal plate 33 can be increased. These spaces are not limited to the examples shown in FIG. 14, and they may be equal to, or different from, each other, for example.

By using the plurality of second electrodes 220-1 to 220-4 configured in such a manner, the second electrodes 220 can be easily positioned to surround the sleeve 61.

A first jig 310 is inserted between the second electrode 220-1 and the second electrode 220-4; a second jig 310 is inserted between the second electrode 220-1 and the second electrode 220-2; and a third jig 310 is inserted between the second electrode 220-2 and the second electrode 220-3. A jig 320 is inserted between the second electrode 220-1 and the second electrode 220-4.

The three jigs 310 and the jig 320 are arranged so as to surround the sleeve 61B and touch the outer periphery of the sleeve 61B during the resistance welding. The positional relationship between the three jigs 310 is fixed by a member (not-shown). On the other hand, the jig 320 is movable in a direction away from the three jigs 310, to a position where the sleeve 61B can pass between the second electrode 220-3 and the second electrode 220-4.

The jigs 310 and 320 are not in contact with the second electrode 220 and are electrically insulated from the second electrodes 220. The jigs 310 and 320 are made of an insulating material, such as a ceramic, a resin composition, or the like. The jigs 310 and 320 may be made of a conductive material, such as a metal material or the like, as long as they are electrically insulated from the second electrodes 220. In this case, the jigs 310 and 320 may also serve as the first electrode 210.

As described above, in the joining step S20, the sleeve 61B is held by the jigs 310 and 320 through the spaces between the plurality of second electrodes 220. Accordingly, even if the second electrodes 220 are disposed so as to surround the sleeve 61B, the position and orientation of the sleeve 61B during resistance welding can be stabilized.

According to the third embodiment described above, the reliability of the semiconductor module can also be improved. It is to be noted that the configuration including the number, shape, etc., of the second electrodes 220 and the jigs 310 and 320 is not limited to the example illustrated in FIG. 14. For example, the number of the second electrodes 220 may be two, three, or five or more.

### 4. Fourth Embodiment

In the following, a fourth embodiment of the present disclosure will be described. In the embodiment illustrated below, elements for which actions and functions are the same as those of the above-described embodiment will be described with reference to the reference numerals used in the description of the above-described embodiment, and detailed descriptions thereof will be omitted as appropriate.

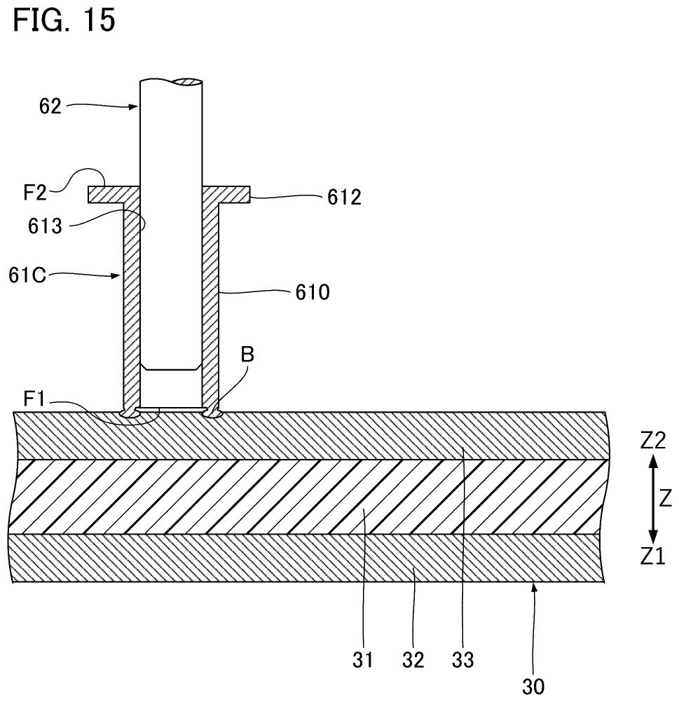

FIG. 15 is an explanatory view of a sleeve 61C according to the fourth embodiment. The present embodiment is the same as the first embodiment except that the sleeve 61C is used in place of the sleeve 61 of the first embodiment.

The sleeve 61C is configured similarly to the sleeve 61 of the first embodiment except that the first flange 611 of the first embodiment and the plurality of projections 614 on the second end face F2 are omitted.

In the embodiment illustrated in FIG. 15, the first end face F1 is constituted of an end face of the tubular portion 610 that faces the Z1 direction. The first end face F1 extends along a plane perpendicular to the Z-axis. The second end face F2 is constituted of an end face of the tubular portion 610 in the Z2 direction and a face of the second flange 612 that faces the Z2 direction. The second end face F2 is a plane perpendicular to the Z-axis.

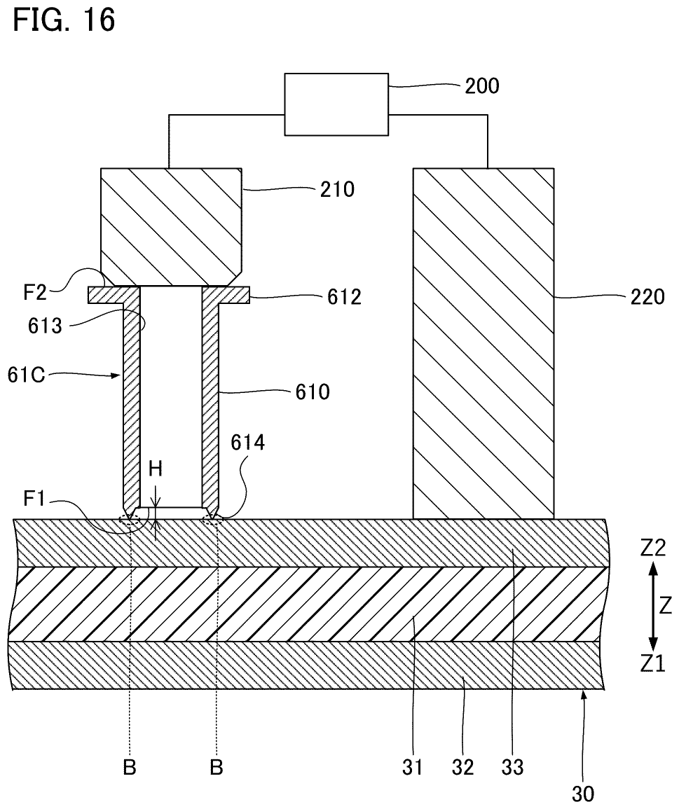

FIG. 16 is an explanatory view of the joining step S20 in the fourth embodiment. In the joining step S20 of the present embodiment, the first end face F1 of the sleeve 61C is joined to the metal plate 33 by resistance welding. Specifically, the plurality of projections 614 provided on the first end face F1 is melted into the metal plate 33, thereby forming a plurality of weld marks B.

In the present embodiment, since the plurality of projections 614 is not provided on the second end face F2, the contact area between the first electrode 210 and the sleeve 61C can be easily increased without requiring modification of the shape of the first electrode 210. Moreover, because the sleeve 61C has the second flange 612 and no projections 614 are provided on the second end face F2, the contact area between the first electrode 210 and the second end face F2 can be easily increased.

According to the fourth embodiment described above, the reliability of the semiconductor module can also be improved.

### 5. Modifications

Specific variations added to the embodiments illustrated above are exemplified below. Two or more aspects freely selected from the following examples may be combined as appropriate so long as there is no conflict.

### 5-1. Modification 1

In the above-described embodiments, a configuration in which at least one projection 614 is provided on the first end face F1 is given as an example. However, the present disclosure is not limited thereto. It is sufficient that the cross-sectional area of the current path by the resistance welding between the metal plate 33 and the first end face F1 or between the metal plate 33A and the first end face F1 can be made smaller than the area of the first end face F1.

For example, the projection 614 may be omitted in the sleeve 61A of the second embodiment. In this case, in the second embodiment, by making the curvature of the concave, curved portion 331 smaller than the curvature of the first end face F1 of the convex, curved shape, or by using the metal plate 33 having no recessed portion 331, the cross-sectional area of the current path can be made smaller than the area of the first end face F1.

Furthermore, even if the projection 614 is not provided on the first end face F1, the cross-sectional area of the current path can be made smaller than the area of the first end face F1 by providing a projection contacting the first end face F1 on the metal plate 33 or the metal plate 33A.

Furthermore, even if the projection 614 is not provided on the first end face F1, the cross-sectional area of the current path can be made smaller than the area of the first end face F1 by disposing a welding member, such as a metal piece or the like, having a cross-sectional area smaller than that of the first end face F1, between the first end face F1 and the metal plate 33 or between the first end face F1 and the metal plate 33A.

### 5-2. Modification 2

In the above-described embodiments, the semiconductor chip 40 and the like are sealed by the frame 71, the potting material PA, and the lid 72, but the present disclosure is not limited thereto. The present disclosure is also applicable to a full mold which is a configuration in which the semiconductor chip 40 and the like are sealed by a single resin composition.

### 5-3. Modification 3

In the above embodiment, the semiconductor chip 40 is an RC-IGBT, but the configuration of the semiconductor chip 40 is not limited to the above example. For example, various electronic devices such as an IGBT (Insulated Gate Bipolar Transistor), an SBD (Schottky Barrier Diode), or the like may be used as the semiconductor chip 40. Furthermore, a MOSFET (Metal-Oxide-Semiconductor Field-Effect Transistor) in which the semiconductor layers are formed from silicon (Si) or silicon carbide (SiC) may be used as the semiconductor chip 40. In a configuration in which the semiconductor chip 40 is made of MOSFET, the first electrode 41 is a drain electrode and the second electrode 42 is a source electrode.

### 6. Appendices

For example, the following configuration can be understood from the embodiments exemplified above.

### APPENDIX 1

A first aspect, which is a preferred example of the semiconductor module of the present disclosure includes: an insulating substrate with an insulating plate and a metal plate joined to one face of the insulating plate; a tubular sleeve with a first end face joined to the metal plate and a second end face opposite to the first end face; and a pin inserted into the sleeve, in which at least one weld mark is formed by resistance welding on the first end face and a surface of the metal plate that faces the first end face, and an area of the at least one weld mark formed by resistance welding is less than an area of the first end face.

In the above aspect, since the sleeve is joined to the metal plate by resistance welding, a first advantage is obtained in that the sleeve is not significantly inclined or displaced relative to the substrate when the metal plate and the sleeve are joined to each other. Furthermore, the join strength between the metal plate and the sleeve can be increased as compared with a configuration in which the sleeve is joined to the metal plate by soldering. Therefore, even if the load applied to the pin is concentrated at the joined portion between the metal plate and the sleeve, a second advantage also is obtained in that the joined portion between the metal plate and the sleeve is not significantly affected by deterioration due to temperature cycling. Moreover, since the area of the weld mark by resistance welding is smaller than the area of the first end face, the time required for joining the metal plate and the sleeve to each other can be shortened. Therefore, the first advantage is preferably obtained, and the heat at the time of joining the metal plate and the sleeve is prevented from adversely affecting the other parts.

### APPENDIX 2

In a second aspect, which is a preferred example of the first aspect, the sleeve has a flange including the second end face. In the above aspect, the contact area between the electrode for resistance welding and the second end face can be increased.

### APPENDIX 3

In a third aspect, which is a preferred example of the first aspect or the second aspect, the sleeve has a tubular shape with a bottom, with the first end face serving as a bottom face, and the at least one weld mark includes a weld mark that includes a center of the first end face. In the above aspect, since the current is easily concentrated at the center of the first end face during resistance welding, the time required for joining the metal plate and the sleeve can be extremely short.

### APPENDIX 4

In a fourth aspect, which is a preferred example of the third aspect, the first end face has a curved shape that protrudes toward the insulating plate. According to the aspect described above, it is possible to make the portion other than the center of the first end face unlikely to come into contact with the metal plate at the time of resistance welding. Therefore, it is easy to concentrate the current at the center of the first end face during resistance welding.

### APPENDIX 5

In a fifth aspect, which is a preferred example of the fourth aspect, the metal plate has a recessed portion having a shape corresponding to the first end face, and the first end face is inserted into the recessed portion. According to the above aspect, the position and the orientation of the sleeve at the time of resistance welding can be stabilized.

### APPENDIX 6

In a sixth aspect, which is a preferred example of the first aspect, the at least one weld mark comprises a plurality of weld marks, and the plurality of weld marks is scattered circumferentially along an outer periphery or an inner periphery of the first end face. According to the above-described aspect, it is possible to stabilize the orientation of the sleeve during resistance welding, eliminating the need to form a recessed portion on the metal plate for inserting the first end face.

### APPENDIX 7

A seventh aspect, which is a preferred example of a method for manufacturing a semiconductor module of the present disclosure includes a preparation step of preparing: an insulating substrate with an insulating plate and a metal plate joined to one face of the insulating plate, and a tubular sleeve with a first end face, a second end face opposite to the first end face, and an opening provided on the second end face; a joining step of joining the first end face to the metal plate by resistance welding; and an insertion step of inserting a pin into the sleeve, in which, in the joining step, a cross-sectional area of a current path by the resistance welding between the metal plate and the first end face is less than an area of the first end face.

In the above aspect, since the sleeve is joined to the metal plate by resistance welding, a first advantage is obtained in that the sleeve is not significantly inclined or displaced relative to the substrate when the metal plate and the sleeve are joined to each other. Furthermore, the join strength between the metal plate and the sleeve can be increased as compared with a configuration in which the sleeve is joined to the metal plate by soldering. Therefore, even if the load applied to the pin is concentrated at the joined portion between the metal plate and the sleeve, a second advantage also is obtained in that the joined portion between the metal plate and the sleeve is only slightly affected by deterioration due to temperature cycling. Moreover, in the joining step, since the cross-sectional area of the current path by resistance welding between the metal plate and the first end face is smaller than the area of the first end face, the time required for joining the metal plate and the sleeve can be shortened. Therefore, the first advantage is preferably obtained, and the heat at the time of joining the metal plate and the sleeve is prevented from adversely affecting the other parts.

### APPENDIX 8

In an eighth aspect, which is a preferred example of the seventh aspect, the sleeve has a flange including the second end face. In the above aspect, the contact area between the electrode for resistance welding and the second end face to each other can be increased.

### APPENDIX 9

In a ninth aspect, which is a preferred example of the seventh aspect or the eighth aspect, in the preparation step, the sleeve is prepared, in which at least one first projection having a width smaller than a width of the sleeve is provided on the first end face, and the joining step joins the metal plate and the at least one first projection to each other by the resistance welding. In the above aspect, the cross-sectional area of the current path for resistance welding between the metal plate and the first end face can be made smaller than the area of the first end face.

### APPENDIX 10

In a tenth aspect, which is a preferred example of the ninth aspect, the sleeve has a tubular shape with a bottom, with the first end face serving as a bottom face, and the at least one first projection includes a projection that includes a center of the first end face. In the above aspect, since the current is easily concentrated at the center of the first end face during resistance welding, the time required for joining the metal plate and the sleeve can be extremely short.

### APPENDIX 11

In the eleventh embodiment, which is a preferred example of the tenth embodiment, the first end face has a curved shape that protrudes toward the insulating plate. According to the aspect described above, it is possible to make a portion other than the center of the first end face unlikely to come into contact with the metal plate at the time of resistance welding. Therefore, it is easy to concentrate the current at the center of the first end face during resistance welding.

### APPENDIX 12

In a twelfth aspect, which is a preferred example of the eleventh aspect, the metal plate has a recessed portion having a shape corresponding to the first end face, and in the joining step, the first end face is inserted into the recessed portion. According to the above aspect, the position and the orientation of the sleeve at the time of resistance welding can be stabilized.

### APPENDIX 13

In a thirteenth aspect, which is a preferred example of the ninth aspect, the at least one first projection comprises a plurality of projections. According to the above-described aspect, it is possible to stabilize the orientation of the sleeve during resistance welding, eliminating the need to form a recessed portion on the metal plate for inserting the first end face.

### APPENDIX 14

In a fourteenth aspect, which is a preferred example of the thirteenth aspect, the second end face is provided with at least one second projection, and in the preparation step, the sleeve is symmetrical in a direction of a length of the sleeve. According to the above-described aspect, it is possible to eliminate the distinction between the upper side and the lower side of the sleeve. Therefore, it is possible to increase the working efficiency of the resistance welding.

### APPENDIX 15

In the fifteenth aspect, which is the preferred example of any of the seventh to fourteenth aspects, the joining step performs the resistance welding by supplying a current between a first electrode in contact with the sleeve and at least one second electrode in contact with the metal plate. In the above aspect, even if the insulating plate is provided on the other surface of the metal plate, a current for resistance welding can flow between the metal plate and the first end face of the sleeve.

### APPENDIX 16

In a sixteenth aspect, which is a preferred example of the fifteenth aspect, in the joining step, the at least one second electrode surrounds the sleeve. In the above aspect, the current path between the first electrode and the second electrode can be shortened, and the current between the metal plate and the first end face can be made uniform.

### APPENDIX 17

In a seventeenth embodiment, which is a preferred example of the sixteenth embodiment, the at least one second electrode comprises a plurality of second electrodes. According to the above aspect, the second electrodes can be easily arranged so as to surround the sleeve.

### APPENDIX 18

In the eighteenth aspect, which is the preferred example of either the sixteenth aspect or the seventeenth aspect, the sleeve is held by a jig through a space between the plurality of second electrodes. According to the above aspect, even if the second electrode is disposed to surround the sleeve, the position and the orientation of the sleeve at the time of resistance welding can be stabilized.

### DESCRIPTION OF REFERENCE SIGNS

30 . . . insulating substrate, 30A . . . insulating substrate, 31 . . . insulating plate, 32 . . . heat dissipation plate, 33A . . . metal plate, 34 . . . joining material, 40 . . . semiconductor chip, 41 . . . first electrode, 42 . . . second electrode, 50 . . . wire, 60 . . . external terminal, 61, 61A, 61B . . . sleeve, 62 . . . pin, 70 . . . case, 71 . . . frame, 72 . . . lid, 72a . . . through hole, 100 . . . semiconductor module, 210 . . . first electrode, 220, 220-1, 220-2, 220-3, 220-4 . . . second electrode, 310, 320 . . . jig, 331 . . . recessed portion, 400 . . . heat dissipation structure, 610 . . . tubular portion, 611 . . . first flange, 612 . . . second flange, 613 . . . inner circumferential surface, 614 . . . projection, 615 . . . bottom portion, B . . . weld mark, F1 . . . first end face, F2 . . . second end face, H . . . height, PA . . . potting material, S10 . . . preparation step, S20 . . . joining step, S30 . . . insertion step, T . . . thickness, W0, Wa, Wb . . . width, W1 . . . distance.

What is claimed is:

1. A semiconductor module comprising:
an insulating substrate with an insulating plate and a metal plate joined to one face of the insulating plate;
a tubular sleeve with a first end face joined to the metal plate and a second end face opposite to the first end face; and
a pin inserted into the tubular sleeve,
wherein at least one weld mark is formed by resistance welding on the first end face and a surface of the metal plate that faces the first end face, and
wherein an area of the at least one weld mark formed by resistance welding is less than an area of the first end face.

2. The semiconductor module according to claim 1, wherein the tubular sleeve has a flange including the second end face.

3. The semiconductor module according to claim 1,
wherein the tubular sleeve has a tubular shape with a bottom, with the first end face serving as a bottom face, and
wherein the at least one weld mark includes a weld mark that includes a center of the first end face.

4. The semiconductor module according to claim 3, wherein the first end face has a curved shape that protrudes toward the insulating plate.

5. The semiconductor module according to claim 4,
wherein the metal plate has a recessed portion having a shape corresponding to the first end face, and
wherein the first end face is inserted into the recessed portion.

6. The semiconductor module according to claim 1,
wherein the at least one weld mark comprises a plurality of weld marks, and
wherein the plurality of weld marks is scattered circumferentially along an outer periphery or an inner periphery of the first end face.

7. A method of manufacturing a semiconductor module, comprising:
a preparation step of preparing:
an insulating substrate with
an insulating plate, and
a metal plate joined to one face of the insulating plate, and
a tubular sleeve with
a first end face,
a second end face opposite to the first end face, and
an opening provided on the second end face;
a joining step of joining the first end face to the metal plate by resistance welding; and
an insertion step of inserting a pin into the tubular sleeve,
wherein, in the joining step, a cross-sectional area of a current path by the resistance welding between the metal plate and the first end face is less than an area of the first end face.

8. The method of manufacturing the semiconductor module according to claim 7, wherein the tubular sleeve has a flange including the second end face.

9. The method of manufacturing the semiconductor module according to claim 7,
wherein, in the preparation step, at least one first projection having a width smaller than a width of the tubular sleeve is provided on the first end face, and
wherein the joining step joins the metal plate and the at least one first projection to each other by the resistance welding.

10. The method of manufacturing the semiconductor module according to claim 7,
wherein the tubular sleeve has a tubular shape with a bottom, with the first end face serving as a bottom face, and
wherein the at least one first projection includes a projection that includes a center of the first end face.

11. The method of manufacturing the semiconductor module according to claim 10, wherein the first end face has a curved shape that protrudes toward the insulating plate.

12. The method of manufacturing the semiconductor module according to claim 11,
wherein the metal plate has a recessed portion having a shape corresponding to the first end face, and
wherein, in the joining step, the first end face is inserted into the recessed portion.

13. The method of manufacturing the semiconductor module according to claim 7, wherein the at least one first projection comprises a plurality of projections.

14. The method of manufacturing the semiconductor module according to claim 13,
wherein the second end face is provided with at least one second projection, and
wherein in the preparation step, the tubular sleeve is symmetrical in a direction of a length of the tubular sleeve.

15. The method of manufacturing the semiconductor module according to claim 7,
wherein the joining step performs the resistance welding by supplying a current between:
a first electrode in contact with the tubular sleeve, and
at least one second electrode in contact with the metal plate.

16. The method of manufacturing the semiconductor module according to claim 15, wherein the at least one second electrode comprises a plurality of second electrodes.

17. The method of manufacturing the semiconductor module according to claim 16, wherein, in the joining step, the at least one second electrode surrounds the tubular sleeve.

18. The method of manufacturing the semiconductor module according to claim 16, wherein in the joining step, the tubular sleeve is held by a jig through a space between the plurality of second electrodes.
